(19) United States
(12) Patent Application Publication
(10) Pub. No.: US 2026/0328810 A1
(43) Pub. Date: Oct. 22, 2026

(54) HIGH-FREQUENCY TRANSMISSION PROBE CONNECTOR STRUCTURE AND FABRICATION PROCESS THEREFOR

(71) Applicant: DONGGUAN LANYI ELECTRONIC TECHNOLOGY CO., LTD, Dongguan (CN)

(72) Inventors: Jiaming Liang, Kaohsiung (TW); Yudi Min, Dongguan (CN); Bert xiao, Dongguan (CN); Bingchao tu, Dongguan (CN)

(21) Appl. No.: 19/695,613

(22) Filed: Jun. 2, 2026

(30) Foreign Application Priority Data
Apr. 27, 2026 (CN) 202610561076.4

(51) Int. Cl. G01R 1/067; G01R 3/00

(52) U.S. Cl. CPC G01R 1/06772; G01R 1/06705; G01R 1/06722; G01R 1/06761; G01R 3/00

(57) ABSTRACT

Disclosed are a high-frequency transmission probe connector structure and a fabrication process therefor. The probe connector structure includes a hollow tube body, where a probe body is disposed at an end of the tube body, and the tube body partially surrounds the probe body; the tube body has a first inner diameter and a second inner diameter, and a portion of an outer wall of the probe body contacts an inner wall of the first inner diameter; a spring is disposed in the tube body, and the spring is located in the first inner diameter; a first limiting portion is formed between the first inner diameter and the second inner diameter; one end of the spring abuts against the probe body, and the other end abuts against the first limiting portion; and an insulating cover is disposed outside the tube body, and the insulating cover surrounds the tube body.

### TECHNICAL FIELD

The present disclosure relates to the field of connector structures, and in particular to a high-frequency transmission probe connector structure and a fabrication process therefor.

### BACKGROUND

A high-frequency transmission connector socket for a servo workstation is a core connecting component designed for ultra-high-speed, high-reliability signal transmission in a servo system. Its core functions revolve around signal interaction, device coordination, and scenario adaptation of the servo workstation. Due to its geometry and open arrangement, a conventional leaf-spring connector generates severe parasitic capacitance and inductance effects under high-frequency signals. As a transmission rate increases to 448 Gbps, impedance discontinuity caused by a leaf-spring structure leads to significant return loss, such that the signal quality fails to meet industrial standards. Furthermore, for the conventional connector, it is difficult to provide complete electromagnetic shielding for a differential pair at a plugging interface. At an extremely high frequency of 448 Gbps, signals are prone to radiating energy outward (EMI) and are highly susceptible to environmental interference. The existing leaf-spring structure, while achieving the convenience of “plug-and-play”, usually fails to provide a closed shielding structure as in a coaxial cable, resulting in signal integrity (SI) collapse.

### SUMMARY

To solve the above problems, the present disclosure provides a high-frequency transmission probe connector structure, including a hollow tube body, where a probe body is disposed at an end of the tube body, the tube body partially surrounds an outer surface of the probe body, and the probe body is movable in the tube body along an axial direction of the tube body; the tube body has a first inner diameter and a second inner diameter, and a portion of an outer wall of the probe body contacts an inner wall of the first inner diameter; a spring is disposed in the tube body, and the spring is located in the first inner diameter; a first limiting portion is formed between the first inner diameter and the second inner diameter; one end of the spring abuts against the probe body, and the other end thereof abuts against the first limiting portion; and an insulating cover is disposed outside the tube body, and the insulating cover surrounds the tube body.

Further, a support ring is disposed between the insulating cover and the tube body, and the support ring is located between an inner wall of the insulating cover and an outer wall of the tube body.

Further, a limiting groove is formed in the support ring, and limiting blocks configured to cooperate with the limiting groove are disposed at both ends of the insulating cover; and when the insulating cover is assembled with the support ring, the limiting blocks are fitted into the limiting groove.

Further, tapered indentation points are formed by recessing the tube body inwardly, the indentation points are located on an outer wall of the second inner diameter, and the indentation points are arranged at intervals of 90°.

Further, a ring-shaped second limiting portion is disposed on a side of the probe body away from the spring, and a constriction portion cooperating with the second limiting portion is disposed on the tube body; and when the spring is compressed and the probe body moves in a reverse direction, the second limiting portion abuts against the constriction portion.

The present disclosure further provides a fabrication process for a high-frequency transmission probe connector structure, including the following steps:
step 1, selecting ultra-high strength ultra-fine piano steel wires, selecting a wire with a diameter of 0.03-0.04 mm according to a winding diameter ratio of 4.5:1 and an assembly space of a tube body, and ensuring a wire diameter tolerance of ≤±2 μm, a tensile strength of ≥3,000 MPa, and an elastic modulus of ≥210 GPa; winding the wire at a low and uniform speed, and adjusting tension in real time using a closed-loop tension control system; monitoring a wound outer diameter in real time using a laser displacement sensor, with calibration performed once per turn to ensure a wound outer diameter error of ≤±0.003 mm; adjusting a free length in real time using a micro-positioning system, ensuring an error of ≤±0.03 mm; and controlling the number of coils of a spring to be 10-12 coils per mm to form a spring;
step 2, selecting a tungsten wire with a diameter of 0.18-0.23 mm as a mandrel, and processing the mandrel using a micro-swaging forming process to form a first inner diameter and a second inner diameter; performing electrolytic polishing on the mandrel to ensure a surface roughness Ra of ≤0.03 μm, and discarding the mandrel having surface scratches or impurities through microscopic inspection; vertically suspending the qualified mandrel in an electroforming tank, electroforming the mandrel to a target wall thickness, ensuring that the first inner diameter and second inner diameter are controlled within 0.2-0.25 mm and the outer diameter error is ≤±5 μm, and completing electroforming; placing a tube body with an outer layer of the mandrel stripped off into a shaping device for radial shaping; and then dissolving and removing the remaining portion of the mandrel, and leaving the tube body;
step 3, selecting beryllium copper alloy, forming the beryllium copper alloy by micro-electroforming+precision grinding, and designing a diameter of a probe body according to the first inner diameter of the tube body, with an error of ≤±5 μm; pretreating an end of the tube body: selecting a qualified tube body, cutting an end of the tube body using a laser cutting machine (equipped with a microscopic positioning module) shared with spring cutting, with a cutting precision of ±0.001 mm, and ensuring a flat end without burrs or deformation; finely grinding the cut end of the tube body using a miniature grinding wheel to remove sharp edges and burrs; micro-grinding the probe body to a final shape; and placing the ground probe body into a phosphoric acid-sulfuric acid mixed solution to ensure a surface roughness Ra of ≤0.015 μm; and
step 4, first, precisely implanting the spring into the tube body, then implanting the probe body into the tube body, monitoring a probe stroke in real time using a laser displacement sensor in conjunction with the spring, and adjusting an assembly position in a closed-loop manner to ensure a stroke precision of ±0.02 mm; detecting a fitting clearance between the probe body and the tube body in real time using a multifunctional hole-shaft clearance measurement system adapted for hole-shaft measurement, to ensure that the clearance is controlled within 0.003-0.013 mm, thereby avoiding seizure caused by an excessively small clearance or excessive friction caused by an excessively large clearance; and after assembling each probe, testing the probe stroke and the fitting clearance to ensure that they meet design requirements.

Further, in the step 1, a winding speed of the steel wire is 80-100 r/min, and a winding tension thereof is 3-5 N.

Further, in the step 2, a straightness is controlled to be ≤0.001 mm/m; tube body dimensions are calibrated: the first inner diameter and the second inner diameter are 0.2-0.25 mm, and a total length is 2.0-2.5 mm; and subsequently, the electroformed tube body and the mandrel are placed into a 4.5% NaOH solution, with a temperature controlled at 78±2 °C, and the mandrel is dissolved for 18-22 min to ensure complete dissolution of the tungsten wire mandrel.

Further, in the step 3, a grinding speed is 9,000-11,000 r/min; and the ground probe body is placed into the phosphoric acid-sulfuric acid mixed solution, with a temperature controlled at 58±3 °C, and polished for 2.5-3.5 min at a current density of 0.6-0.9 A/dm².

Further, the spring is precisely implanted into the tube body using a vacuum suction and microscopic positioning configuration, with an installation coaxiality of the spring controlled to be ≤0.005 mm, and then the probe body is implanted into the tube body.

Compared with the prior art, the present disclosure has the following beneficial effects:

By disposing the smoothly transitioning first inner diameter and second inner diameter in the tube body, the present disclosure enables a wire core and the probe body to achieve maximized coaxial transmission within the tube body. This design can effectively isolate external electromagnetic interference and suppress crosstalk, and provide a necessary signal-to-noise ratio margin for PAM6, thereby achieving an extremely low bit error rate at a single channel of 448 Gbps.

Additional aspects and advantages of the present disclosure will be given in the following description, and in part will be apparent from the following description, or will be understood through the practice of the present disclosure.

### BRIEF DESCRIPTION OF THE DRAWINGS

In order to explain the technical solutions in embodiments of the present disclosure or in the prior art more clearly, the drawings to be used in the embodiments or the prior art will be briefly introduced below. Obviously, the drawings described below are only some embodiments of the present disclosure. For those of ordinary skill in the art, other drawings may be obtained based on these drawings without making creative efforts.

FIG. 1 is a schematic view of an overall structure of the present disclosure.

FIG. 2 is an exploded view of an overall structure of the present disclosure.

FIG. 3 is a sectional view of a tube body and a probe body of the present disclosure.

FIG. 4 is an analysis diagram of insertion loss and return loss of the present disclosure.

FIG. 5 is an analysis diagram of impedance control of the present disclosure.

Reference numerals and designations in the figures:
100—tube body; 200—probe body; 300—spring; 110—first limiting portion; 400—insulating cover; 500—support ring; 510—limiting groove; 410—limiting block; 120—indentation point; 210—second limiting portion; 130—constriction portion; 600—wire core; and 700—shielding shell.

### DESCRIPTION OF EMBODIMENTS

The technical solutions in embodiments of the present disclosure will be clearly and completely described below. It is obvious that the described embodiments are only a part of, rather than all of, the embodiments of the present disclosure. Based on the embodiments in the present disclosure, all other embodiments obtained by those of ordinary skill in the art without making creative efforts should fall within the protection scope of the present disclosure.

The present disclosure will be explained in more detail. It should be understood that the specific embodiments described herein are used only for explaining the present disclosure, rather than limiting the present disclosure. It should be noted that when an element is expressed to be “fixed to” another element, it means that the element may be directly on another element, or one or more intervening elements may also be present. When an element is expressed to be “connected” to another element, the element may be directly connected to another element, or one or more intervening elements may also be present.

In the description of the present disclosure, it should be noted that orientations or positional relations indicated by directional terms “front”, “rear”, “upper”, “lower”, “left”, “right”, “transverse”, “vertical”, “perpendicular”, “horizontal”, “top”, and “bottom” are based on orientations or positional relations shown in the drawings and are only for facilitating the description of the present disclosure and simplifying the description, and do not indicate or imply that a device or element involved must have a particular orientation or be constructed and operated in a particular orientation, unless expressly stated otherwise. Therefore, these directional terms should not be construed as a limitation to the protection scope of the present disclosure. Directional terms “inner” and “outer” refer to the interior and exterior relative to contours of respective components themselves. In the description of the present disclosure, it should be noted that terms “first” and “second” are used to define components merely for the purpose of distinguishing between corresponding components. Unless otherwise stated, the terms have no special meanings. Therefore, these terms should not be construed as limiting the protection scope of the present disclosure. In the present disclosure, the term “a plurality of” refers to two or more, unless otherwise specifically defined.

Unless otherwise defined, all technical and scientific terms used in the specification have the same meanings as commonly understood by those skilled in the technical field of the present disclosure. Terms used in the specification of the present disclosure are used only for the purpose of describing specific embodiments, and are not intended to limit the present disclosure.

In addition, the technical features described below and involved in different embodiments of the present disclosure may be combined with each other, as long as there is no conflict.

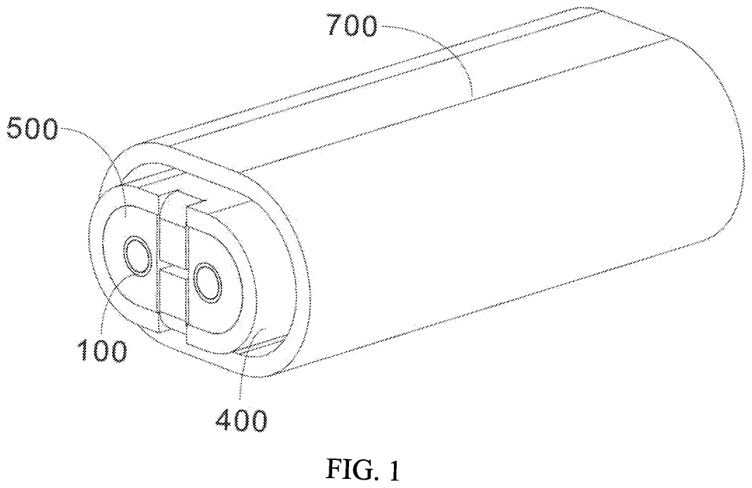

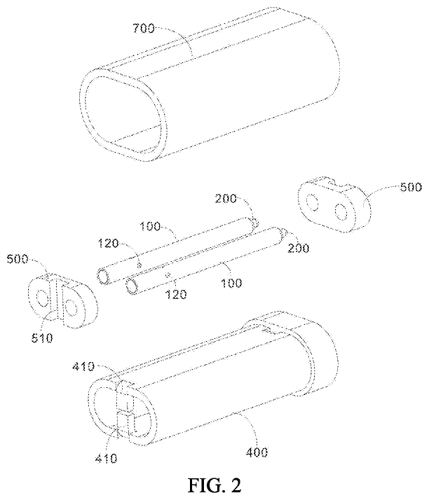

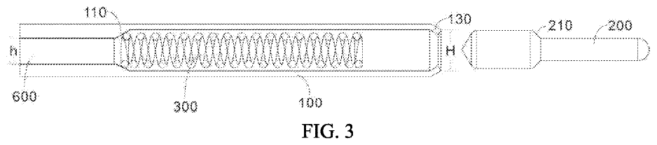

Now, a preferred embodiment of the present disclosure will be further described with reference to the drawings. As shown in FIGS. 1, 2, and 3, a high-frequency transmission probe connector structure includes a hollow tube body 100, where a probe body 200 is disposed at an end of the tube body 100, the tube body 100 partially surrounds an outer surface of the probe body 200, and the probe body 200 is movable in the tube body 100 along an axial direction of the tube body 100; the tube body 100 has a first inner diameter (indicated by a reference letter H in FIG. 3) and a second inner diameter (indicated by reference letter h in FIG. 3), and a portion of an outer wall of the probe body 200 contacts an inner wall of the first inner diameter; a spring 300 is disposed in the tube body 100, and the spring 300 is located in the first inner diameter; a first limiting portion 110 is formed between the first inner diameter and the second inner diameter; one end of the spring 300 abuts against the probe body 200, and the other end thereof abuts against the first limiting portion 110; and an insulating cover 400 is disposed outside the tube body 100, and the insulating cover 400 surrounds the tube body 100.

The present disclosure is mainly applied to an AI server requiring high-performance computing, and is particularly suitable for high-frequency transmission operations in a 448 Gbps PAM6 servo workstation. It is a core component designed for ultra-high-speed, high-reliability signal transmission in a servo system. During implementation of the present disclosure, the probe body 200 is first fitted in the tube body 100; the smoothly transitioning first inner diameter and second inner diameter are disposed in the tube body 100, where the first inner diameter is configured to accommodate the probe body 200, and the second inner diameter is configured to accommodate an external wire core 600; then, the spring 300 is mounted in the tube body 100 such that one end of the spring 300 abuts against the probe body 200, and the other end thereof is sleeved and fixed around the wire core 600, such that the other end of the spring 300 abuts against the wire core 600. During use, the tube body 100 is configured to be plugged into a corresponding device, and an electrical signal is transmitted through the core 600, the spring 300, and the probe body 200 in order.

Compared with the prior art, by disposing the smoothly transitioning first inner diameter and second inner diameter in the tube body 100, the present disclosure enables the wire core 600 and the probe body 200 to achieve maximized coaxial transmission within the tube body 100. This design can effectively isolate external electromagnetic interference and suppress crosstalk, and provide a necessary signal-to-noise ratio margin for PAM6, thereby achieving an extremely low bit error rate at a single channel of 448 Gbps.

Further based on the above embodiment, a support ring 500 is disposed between the insulating cover 400 and the tube body 100, and the support ring 500 is located between an inner wall of the insulating cover 400 and an outer wall of the tube body 100; and a shielding shell 700 is wrapped around an outer surface of the insulating cover 400. The shielding shell 700 can cooperate with the insulating cover 400 to provide further shielding against external electromagnetic signals, thereby achieving better transmission stability during high-frequency transmission. The support ring 500 can support the insulating cover 400 between the insulating cover 400 and the tube body 100.

Further based on the above embodiment, a limiting groove 510 is formed in the support ring 500, and limiting blocks 410 configured to cooperate with the limiting groove 510 are disposed at both ends of the insulating cover 400; and when the insulating cover 400 is assembled with the support ring 500, the limiting blocks 410 are fitted into the limiting groove 510. This prevents mutual wobbling between the insulating cover 400 and the support ring 500.

Further based on the above embodiment, tapered indentation points 120 are formed by recessing the tube body 100 inwardly, the indentation points 120 are located on an outer wall of the second inner diameter, and the indentation points 120 are arranged at intervals of 90°. Thus, when the wire core 600 is sleeved on the second inner diameter, the indentation points 120 compress a periphery of the wire core 600. Compared with conventional sleeving, the indentation points 120 can enhance sleeving and fixing effects between the tube body 100 and the wire core 600.

Further based on the above embodiment, a ring-shaped second limiting portion 210 is disposed on a side of the probe body 200 away from the spring 300, and a constriction portion 130 cooperating with the second limiting portion 210 is disposed on the tube body 100; and when the spring 300 is compressed and the probe body 200 moves in a reverse direction, the second limiting portion 210 abuts against the constriction portion 130. Thus, the probe body 200 can be prevented from being pushed out of the tube body 100 by the spring 300.

The present disclosure further discloses a fabrication process for a high-frequency transmission probe connector structure, including the following steps:

Step 1, a spring 300 is prepared. Ultra-high strength ultra-fine piano steel wires are selected, a wire with a diameter of 0.03-0.04 mm is selected according to a winding diameter ratio of 4.5:1 and an assembly space of a tube body 100, and the wire is measured using a laser diameter gauge (with an accuracy of ±1 μm) to ensure a wire diameter tolerance of ≤±2 μm, a tensile strength of ≥3,000 MPa, and an elastic modulus of ≥210 GPa; the wire is wound at a low and uniform speed with a winding speed of 80-100 r/min and a winding tension of 3-5 N, and tension is adjusted in real time using a closed-loop tension control system to avoid stretching deformation or breakage of the steel wire; a wound outer diameter is monitored in real time using a laser displacement sensor, with calibration performed once per turn to ensure a wound outer diameter error of ≤±0.003 mm; a free length is adjusted in real time using a micro-positioning system, ensuring an error of ≤±0.03 mm; and the number of coils of the spring 300 is controlled to be 10-12 coils per mm to avoid uneven coil distribution causing elastic force fluctuation.

Step 2, the tube body 100 is prepared. A tungsten wire with a diameter of 0.18-0.23 mm is selected as a mandrel, and processed using a micro-swaging forming process to form a first inner diameter and a second inner diameter, and a smooth transition without steps between the first inner diameter and the second inner diameter is ensured; electrolytic polishing is performed on the mandrel to ensure a surface roughness Ra of ≤0.03 μm, and the mandrel having surface scratches or impurities is discarded through microscopic inspection to avoid affecting the smoothness of an inner wall of the tube body 100; the qualified mandrel is vertically suspended in an electroforming tank and electroformed to a target wall thickness, it is ensured that the first inner diameter and second inner diameter are controlled within 0.2-0.25 mm and the outer diameter error is ≤±5 μm, and electroforming is completed; a tube body 100 with an outer layer of the mandrel stripped off is placed into a shaping device for radial shaping, with a straightness controlled to be ≤0.001 mm/m; dimensions of the tube body 100 are calibrated: the first inner diameter and the second inner diameter are 0.2-0.25 mm (with an outer diameter error of ≤±5 μm), and a designed total length is 2.0-2.5 mm (with a length error of ≤±0.01 mm); and the electroformed tube body 100 and the remaining portion of the mandrel are placed into a 4.5% NaOH solution, with a temperature controlled at 78±2 °C, and the remaining portion of the mandrel is dissolved for 18-22 min to ensure complete dissolution of the tungsten wire mandrel.

Step 3, a probe body 200 is prepared. Beryllium copper alloy of the same material as the tube body 100 is selected and formed by micro-electroforming+precision grinding, and a diameter of a probe body 200 is designed according to the first inner diameter of the tube body 100, with an error of ≤±5 μm; an end of the tube body 100 is pretreated: a qualified tube body 100 is selected, an end of the tube body 100 is cut using a laser cutting machine (equipped with a microscopic positioning module) shared with cutting of the spring 300, with a cutting precision of ±0.001 mm, and a flat end without burrs or deformation is ensured; the cut end of the tube body 100 is finely ground using a miniature grinding wheel to remove sharp edges and burrs; the probe body 200 is micro-ground to a final shape: grinding parameters are set as follows: a grinding speed of 9,000-11,000 r/min, low-speed fine grinding is used to avoid edge chipping or deformation of a probe head; and the ground probe body 200 is placed into a phosphoric acid-sulfuric acid mixed solution (at a volume ratio of 3:1), with a temperature controlled at 58±3 °C, and polished for 2.5-3.5 min at a current density of 0.6-0.9 A/dm², to ensure a surface roughness Ra of ≤0.015 μm.

Step 4, the probe connector structure is assembled. The qualified spring 300 is precisely implanted into the tube body 100 using a vacuum suction and microscopic positioning configuration, with an installation coaxiality of the spring 300 controlled to be ≤0.005 mm; then the probe body 200 is implanted into the tube body 100, a probe stroke is monitored in real time using a laser displacement sensor in conjunction with the spring 300, and an assembly position is adjusted in a closed-loop manner to ensure a stroke precision of ±0.02 mm; a fitting clearance between the probe body and the tube body 100 is detected in real time using a multifunctional hole-shaft clearance measurement system (with a repeatability of ≤0.5 μm) adapted for hole-shaft measurement, to ensure that the clearance is controlled within 0.003-0.013 mm, thereby avoiding seizure caused by an excessively small clearance or excessive friction caused by an excessively large clearance; and after each probe is assembled, the probe stroke and the fitting clearance are tested to ensure that they meet design requirements.

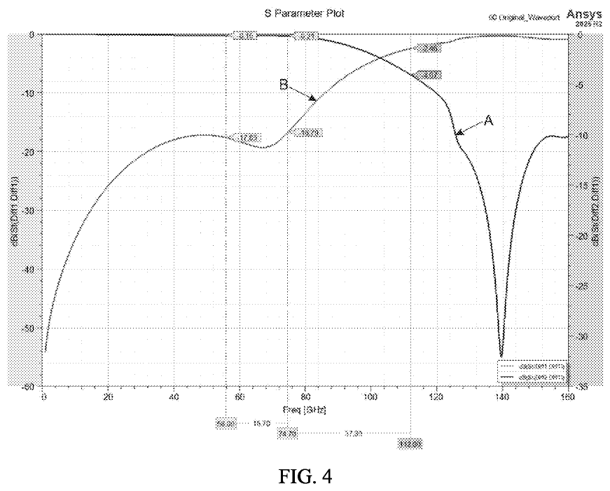

The high-frequency transmission probe connector structure prepared according to the above process, due to good coaxial characteristics, exhibits extremely low insertion loss and return loss. As shown in FIG. 4, an arrow A indicates insertion loss, which is only −0.21 dB. This index is defined as 20 [log]_10(V_out/V_in); in the formula, (V_out/V_in) represents a voltage amplitude at a channel output and a channel input, respectively. This extremely low insertion loss performance is far superior to an industrial specification requirement of −1 dB, thereby ensuring that a voltage margin between levels is maximally preserved during 6-level Pulse Amplitude Modulation (PAM6) multi-level modulated signal transmission, and significantly reducing a bit error rate (BER) during multi-level voltage determination at a receiving end. As shown in FIG. 4, an arrow B indicates return loss. To suppress signal reflection caused by impedance mismatch, the present architecture performs precise impedance control on a physical channel. According to the definition of the return loss, 20 [log]_10(V_reflected/V_incident), the return loss value at 74.7 GHz reaches −16.79 dB, meeting and exceeding a stringent standard of −10 dB. This value indicates that the channel has excellent impedance matching characteristics, can effectively reduce inter-symbol interference (ISI) caused by reflected waves on a transmission line, and can further suppress signal jitter.

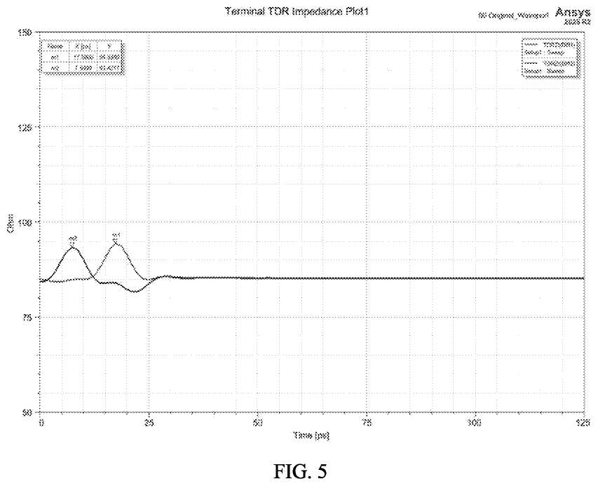

Moreover, the present disclosure also exhibits good impedance control. As shown in FIG. 5, a main part of a path is on a stable reference line of 85 Ω. After detection, impedance disturbance points along the path (e.g., connection sections or corners) exhibit peaks of about 94 Ω and 93.8 Ω respectively. However, under an industrial standard specification of 85 Ω+/−10% (with a permissible range of 76.5 Ω-93.5 Ω), although local disturbance points are slightly close to an upper limit of the specification (93.8 Ω-94 Ω), the overall impedance fluctuation is controlled within an extremely small time-domain range and quickly returns to 85 Ω.

In summary, this mutually corroborates with the return loss data in FIG. 4. For a 448 Gbps PAM6 high-speed multi-level signal, precise impedance matching eliminates potential inter-symbol interference (ISI) along the path, avoids waveform jitter caused by the superposition of a reflected wave and an incident wave, ensures a voltage and time margin at the receiving end during multi-level identification, and provides highly stable physical layer support for an ultra-high-speed communication system.

The present disclosure is not limited to the details of the above exemplary embodiments, and the present disclosure may be implemented in other specific forms under the condition of not deviating from the spirit or basic features of the present disclosure. Therefore, from any point of view, the embodiments should be regarded as exemplary and non-limiting embodiments. The scope of the present disclosure is defined by the attached claims rather than the above description, and thus it is intended to include in the present disclosure all the changes that fall within the meaning and scope of the equivalent elements of the claims.

What is claimed is:

1. A high-frequency transmission probe connector structure, comprising a hollow tube body, wherein a probe body is disposed at an end of the tube body, the tube body partially surrounds an outer surface of the probe body, and the probe body is movable in the tube body along an axial direction of the tube body; the tube body has a first inner diameter and a second inner diameter, and a portion of an outer wall of the probe body contacts an inner wall of the first inner diameter; a spring is disposed in the tube body, and the spring is located in the first inner diameter; a first limiting portion is formed between the first inner diameter and the second inner diameter; one end of the spring abuts against the probe body, and the other end thereof abuts against the first limiting portion; and an insulating cover is disposed outside the tube body, and the insulating cover surrounds the tube body.

2. The high-frequency transmission probe connector structure according to claim 1, wherein a support ring is disposed between the insulating cover and the tube body, and the support ring is located between an inner wall of the insulating cover and an outer wall of the tube body; and a shielding shell is wrapped around an outer surface of the insulating cover.

3. The high-frequency transmission probe connector structure according to claim 2, wherein a limiting groove is formed in the support ring, and limiting blocks configured to cooperate with the limiting groove are disposed at both ends of the insulating cover; and when the insulating cover is assembled with the support ring, the limiting blocks are fitted into the limiting groove.

4. The high-frequency transmission probe connector structure according to claim 1, wherein tapered indentation points are formed by recessing the tube body inwardly, the indentation points are located on an outer wall of the second inner diameter, and the indentation points are arranged at intervals of 90°.

5. The high-frequency transmission probe connector structure according to claim 1, wherein a ring-shaped second limiting portion is disposed on a side of the probe body away from the spring, and a constriction portion cooperating with the second limiting portion is disposed on the tube body; and when the spring is compressed and the probe body moves in a reverse direction, the second limiting portion abuts against the constriction portion.

6. A fabrication process for a high-frequency transmission probe connector structure, comprising the following steps:
step 1, selecting ultra-high strength ultra-fine piano steel wires, selecting a wire with a diameter of 0.03-0.04 mm according to a winding diameter ratio of 4.5:1 and an assembly space of a tube body, and ensuring a wire diameter tolerance of ≤±2 μm, a tensile strength of ≥3,000 MPa, and an elastic modulus of ≥210 GPa; winding the wire at a low and uniform speed, and adjusting tension in real time using a closed-loop tension control system; monitoring a wound outer diameter in real time using a laser displacement sensor, with calibration performed once per turn to ensure a wound outer diameter error of ≤±0.003 mm; adjusting a free length in real time using a micro-positioning system, ensuring an error of ≤±0.03 mm; and controlling the number of coils of a spring to be 10-12 coils per mm to form a spring;
step 2, selecting a tungsten wire with a diameter of 0.18-0.23 mm as a mandrel, and processing the mandrel using a micro-swaging forming process to form a first inner diameter and a second inner diameter; performing electrolytic polishing on the mandrel to ensure a surface roughness Ra of ≤0.03 μm, and discarding the mandrel having surface scratches or impurities through microscopic inspection; vertically suspending the qualified mandrel in an electroforming tank, electroforming the mandrel to a target wall thickness, ensuring that the first inner diameter and second inner diameter are controlled within 0.2-0.25 mm and the outer diameter error is ≤±5 μm, and completing electroforming; placing a tube body with an outer layer of the mandrel stripped off into a shaping device for radial shaping; and then dissolving and removing the remaining portion of the mandrel, and leaving the tube body;
step 3, selecting beryllium copper alloy, forming the beryllium copper alloy by micro-electroforming+precision grinding, and designing a diameter of a probe body according to the first inner diameter of the tube body, with an error of ≤±5 μm; pretreating an end of the tube body: selecting a qualified tube body, cutting an end of the tube body using a laser cutting machine shared with spring cutting, with a cutting precision of ±0.001 mm, and ensuring a flat end without burrs or deformation; finely grinding the cut end of the tube body using a miniature grinding wheel to remove sharp edges and burrs; micro-grinding the probe body to a final shape; and placing the ground probe body into a phosphoric acid-sulfuric acid mixed solution to ensure a surface roughness Ra of ≤0.015 μm; and
step 4, first, precisely implanting the spring into the tube body, then implanting the probe body into the tube body, monitoring a probe stroke in real time using a laser displacement sensor in conjunction with the spring, and adjusting an assembly position in a closed-loop manner to ensure a stroke precision of ±0.02 mm; detecting a fitting clearance between the probe body and the tube body in real time using a multifunctional hole-shaft clearance measurement system adapted for hole-shaft measurement, to ensure that the clearance is controlled within 0.003-0.013 mm, thereby avoiding seizure caused by an excessively small clearance or excessive friction caused by an excessively large clearance; and after assembling each probe, testing the probe stroke and the fitting clearance to ensure that they meet design requirements.

7. The fabrication process for a high-frequency transmission probe connector structure according to claim 6, wherein in the step 1, a winding speed of the steel wire is 80-100 r/min, and a winding tension thereof is 3-5 N.

8. The fabrication process for a high-frequency transmission probe connector structure according to claim 6, wherein in the step 2, a straightness is controlled to be ≤0.001 mm/m; tube body dimensions are calibrated: the first inner diameter and the second inner diameter are 0.2-0.25 mm, and a total length is 2.0-2.5 mm; and subsequently, the electroformed tube body and the mandrel are placed into a 4.5% NaOH solution, with a temperature controlled at 78±2 °C, and the mandrel is dissolved for 18-22 min to ensure complete dissolution of the tungsten wire mandrel.

9. The fabrication process for a high-frequency transmission probe connector structure according to claim 6, wherein in the step 3, a grinding speed is 9,000-11,000 r/min; and the ground probe body is placed into the phosphoric acid-sulfuric acid mixed solution, with a temperature controlled at 58±3 °C, and polished for 2.5-3.5 min at a current density of 0.6-0.9 A/dm².

10. The fabrication process for a high-frequency transmission probe connector structure according to claim 6, wherein the spring is precisely implanted into the tube body using a vacuum suction and microscopic positioning configuration, with an installation coaxiality of the spring controlled to be ≤0.005 mm, and then the probe body is implanted into the tube body.
